(19) United States
(12) Patent Application Publication
(10) Pub. No.: US 2008/0113086 A1
(43) Pub. Date: May 15, 2008

(54) Nanosize Heater-Mounted Nozzle and Method for Manufacturing Same and Method for Forming Micro Thin Film

(75) Inventors: Seiji Akita, Osaka (JP); Yoshikazu Nakayama, Osaka (JP)

Correspondence Address: WENDEROTH, LIND & PONACK, L.L.P., 2033 K STREET N. W., SUITE 800, WASHINGTON, DC, 20006-1021, US

(73) Assignee: JURIDICAL FOUNDATION OSAKA INDUSTRIAL PROMOTION OR, Osaka (JP)

(21) Appl. No.: 10/576,476

(22) PCT Filed: Oct. 21, 2004
(86) PCT No.: PCT/JP04/15598

§ 371 Date: Oct. 18, 2006

(30) Foreign Application Priority Data
Oct. 22, 2003 (JP) 2003-362072
Jul. 23, 2004 (JP) 2004-215944

(51) Int. Cl. C23C 16/00; B05D 5/12

(52) U.S. Cl. 427/58; 118/724; 427/248.1

(57) ABSTRACT

A nanosize heater-mounted nozzle is configured of a nozzle for locally supplying a source gas toward a substrate W; a pair of electrodes located on a side face of the nozzle; and a nanosize heater formed of carbon nanotube or the like, in which the nanosize heater is connected between the electrodes so as to pass over the opening of the nozzle, for heating the source gas by current flowing, whereby easily realizing localized deposition within a limited region on a substrate.

### TECHNICAL FIELD

The present invention relates to a nanosize heater-mounted nozzle using an electrically conductive nanosize material, such as carbon nanotube, a method for manufacturing the same, and a method for forming a micro thin film.

### BACKGROUND

For approaches to form thin films of various materials on a substrate during manufacturing an electronic device, e.g., integrated circuit, or an optical device, utilized are physical deposition process, such as vacuum evaporation or sputtering, or chemical deposition process, such as CVD (chemical vapor deposition) or thermal decomposition.

These methods perform repeatedly steps of a) depositing a thin film on the overall surface of a substrate, b) forming a mask (resist) having fine patterns on the thin film, c) removing by etching a portion of the thin film which is exposed through an opening of the mask, and d) removing the mask used, resulting in a desired thin film device.

Incidentally, related prior arts (for example, the following Japanese patent documents 1 to 5) disclose a process of manufacturing carbon nanotubes, from which the present invention are not different in technical field. 1

[PATENT DOCUMENT 1] JP-2002-255524-A

[PATENT DOCUMENT 2] JP-2001-254897-A

[PATENT DOCUMENT 3] JP-2000-203820-A

[PATENT DOCUMENT 4] JP-2000-164112-A

[PATENT DOCUMENT 5] JP-6-283129-A(1994)

### DISCLOSURE OF THE INVENTION

### Problem to be Solved by the Invention

In the conventional process as described above, a whole substrate is subject to heating, deposition and removing. Hence resultant devices formed on the substrate may be remarkably damaged, thereby requiring many restrictions in terms of process.

Further, in a case of processing a localized region, additional process design for the whole substrate is required, thereby increasing the number of times of processes and cost of manufacture.

It is an object of the present invention to provide a nanosize heater-mounted nozzle, which can easily realize localized deposition within a limited region on a substrate, and also to provide a method for manufacturing the same, and a method for forming a micro thin film.

### Means for Solving the Problem

To achieve the above object, a nanosize heater-mounted nozzle, according to the present invention, includes:

a nozzle for locally supplying a source gas toward a substrate; and

a nanosize heater for heating the source gas, located in the vicinity of an opening of the nozzle.

It is preferable in the present invention that the nanosize heater is composed of carbon nanotube.

Further, it is preferable in the present invention that the nozzle is formed of an electrically insulating material, and a pair of electrodes is located on a side face of the nozzle, and the nanosize heater is connected between the electrodes so as to pass over the opening of the nozzle.

Furthermore, it is preferable in the present invention that the nozzle is formed of quartz or heat-resistant glass.

Furthermore, it is preferable in the present invention that the electrodes are formed of a material having a melting point of 1,700 degree-C. or higher.

In addition, a method for forming a micro thin film, according to the present invention, includes steps of:

positioning the above-described nanosize heater-mounted nozzle closely to a surface of a substrate;

locally supplying a source gas toward the substrate through the nanosize heater-mounted nozzle; and

heating the source gas around an opening of the nozzle while energizing the nanosize heater.

In addition, a method for manufacturing a nanosize heater-mounted nozzle, according to the present invention, includes steps of:

partially heating a tube formed of an electrically insulating material to shape a tapered nozzle by drawing;

forming a pair of electrodes on a side face of the nozzle; and

connecting a nanosize heater between the electrodes so as to pass over an opening of the nozzle.

It is preferable in the present invention that the method further includes a step of evaporating a conductive portion between the electrodes by supplying a current between the electrodes, after forming the pair of electrodes on the side face of the nozzle.

Further, it is preferable in the present invention that the method further includes a step of irradiating with an electron beam the portion connected between each of the electrodes and the nanosize heater, after connecting the nanosize heater between the electrodes.

### EFFECT OF THE INVENTION

According to an aspect of the present invention, the source gas is heated using the nanosize heater located in the vicinity of the opening of the nozzle while being locally supplied through the nozzle, thereby locally causing thermal decomposition reaction and/or chemical reaction of the source gas, so that a thin film can be formed in an extremely small region on the substrate.

In addition, the thin film of desired material can be formed by changing optionally a variety of the source gas supplied to the nozzle. The thin film of desired thickness also can be formed by changing optionally time of deposition. The thin film having an desired pattern also can be formed by changing optionally the position of the nozzle.

Therefore, a micro thin film having any number of layers, any material of layer, and/or any thickness of layer can be locally formed with a desired pattern. Damage to the whole substrate caused by processes is remarkably reduced as compared to the conventional method, and a source gas and energy required for processes can be economized.

Further, carbon nanotubes can work at a temperature as much as 2,400 K (kelvin) in vacuum of about 10⁻⁵ Pa (pascal) without catalysis of, e.g., gold, and can work in an inert gas at a temperature higher than a sublimation point 3,400 K of graphite at an atmosphere pressure, and can stand stable until reaching a temperature as much as 700 degree-C., at which oxidization is initiated in the air. Furthermore, carbon nanotubes have an extremely large allowable current density of about 10⁸ A/cm.

Therefore, utilizing the carbon nanotube as a heater for heating a source gas facilitates localized heating at a higher temperature.

In addition, the nozzle is formed of an electrically insulating material, such as quartz or glass, and the nanosize heater is connected between the pair of electrodes located on the side face of the nozzle, thereby realizing integration of both the nozzle and the nanosize heater with a simple structure. Further, the nanosize heater is arranged to pass over the opening of the nozzle, thereby effectively heating the source gas flowing through the nozzle, and improving efficiency of the source gas.

In particular, the nozzle is preferably formed of quartz or heat-resistant glass, resulting in the nozzle with excellent heat resistance, strength and chemical stability. It is also easy to obtain the nozzle having desired opening diameter and shape due to excellent workability thereof.

Further, the electrodes are preferably formed of a material having a melting point of 1,700 degree-C. or higher, such as platinum Pt (melting point: 1,770 degree-C.), tantalum Ta (m.p.: 2,990 degree-C.), molybdenum Mo (m.p.: 2,620 degree-C.), thereby attaining the nozzle with excellent heat resistance, strength and chemical stability.

According to another aspect of the present invention, the above-described nanosize heater-mounted nozzle is positioned closely to a surface of a substrate, and then a source gas is locally supplied onto the substrate through the nanosize heater-mounted nozzle, and then the source gas is heated around an opening of the nozzle while energizing the nanosize heater, thereby locally causing thermal decomposition reaction and/or chemical reaction of the source gas, so that a thin film can be formed in an extremely small region on the substrate.

Further, such a micro thin film having any number of layers, any material of layer, and/or any thickness of layer can be locally formed with a desired pattern by controlling a variety of the source gas, time of deposition and/or the position of the nozzle. Damage to the whole substrate caused by processes is remarkably reduced as compared to the conventional method, and a source gas and energy required for processes can be economized.

In the method for manufacturing a nanosize heater-mounted nozzle, according to the present invention, a tube formed of an electrically insulating material is partially heated to shape a tapered nozzle by drawing, thereby easily obtaining the nozzle having a desired opening diameter and shape.

In addition, after the pair of electrodes is formed on the side face of the nozzle, a conductive portion between the electrodes is evaporated by supplying a current between the electrodes, thereby attaining a higher insulating resistance between the electrodes, and remarkably suppressing a leakage current. Consequently, efficiency of energy during energizing the heater can be improved.

Moreover, after the nanosize heater is connected between the electrodes, the portion connected between each of the electrodes and the nanosize heater is irradiated with an electron beam, thereby causing a current along the nanosize heater, and then evaporating impurities residing in the connected portion. Consequently, a contact resistance between each of the electrodes and the nanosize heater can be remarkably reduced, and efficiency of energy during energizing the heater can be improved.

### BRIEF DESCRIPTION OF THE DRAWINGS

FIG. 1 is a constructive view showing an example of a multi-wall carbon nanotube according to the present invention.

FIG. 2A is a schematic perspective view showing a first embodiment according to the present invention, and

FIG. 2B is a bottom plan view thereof.

FIG. 3A is a schematic perspective view showing a second embodiment according to the present invention, and

FIG. 3B is a bottom plan view thereof.

FIG. 4A is a schematic perspective view showing a third embodiment according to the present invention, and

FIGS. 4B and 4C are bottom plan views thereof.

FIGS. 5A to 5D are illustrative views showing a fourth embodiment according to the present invention.

### EXPLANATORY NOTE

10 nanosize heater-mounted nozzle

11 nozzle

21, 22 electrode

30 nanosize heater

31 linking member

### BEST EMBODIMENT FOR CARRYING OUT THE INVENTION

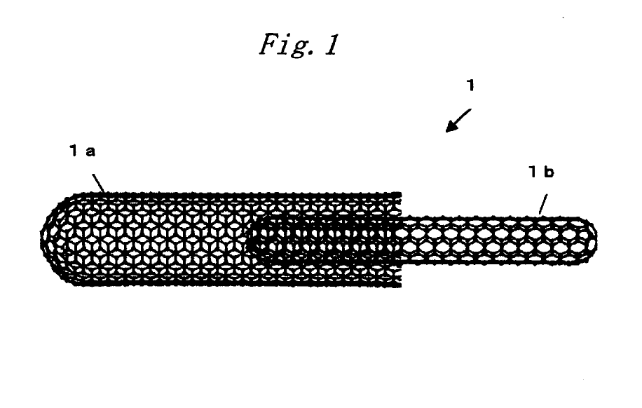

FIG. 1 is a constructive view showing an example of a multi-wall carbon nanotube according to the present invention. For easy understanding, it shows a double-wall carbon nanotube composed of two layers of both an outer tube, which is partially broken, and an inner tube. The present invention also can be applied to a single-wall carbon nanotube and a triple or more wall carbon nanotube.

A multi-walled carbon nanotube 1 includes an outermost tube 1a and an inner tube 1b located inside of the outer tube 1a. Typically, the multi-walled carbon nanotube 1 has a diameter of about 1 to 20 nm (nanometer) and a length of about 0.1 to 10 μm, whose number of layers, diameter and length can be controlled depending on manufacturing condition.

In the outer and inner tubes 10 and 20, hexagon carbon rings, each having six carbon atoms, are periodically arranged to form a cylindrical face, and pentagon carbon rings, each having five carbon atoms, are partially arranged to form a curved face.

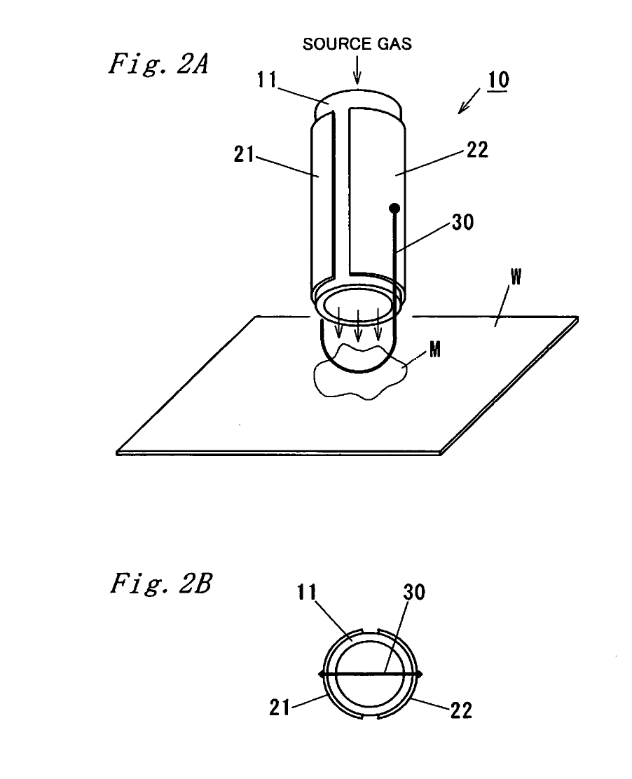

FIG. 2A is a schematic perspective view showing a first embodiment according to the present invention, and FIG. 2B is a bottom plan view thereof. A nanosize heater-mounted nozzle 10 is composed of a nozzle body 11, a pair of electrodes 21 and 22, and a nanosize heater 30.

The nozzle body 11 is formed of an electrically insulating material, such as quartz or glass, so as to have a tubular shape, e.g., cylinder hollow or rectangle hollow. The inner diameter of the nozzle 11 may be optionally designed depending on spatial resolution during deposition of micro thin films, for example, 100 nm to 2 μm. When a source gas is fed from a gas transfer unit through a gas delivery path (not shown) to a rear end of the nozzle 11, the source gas is locally supplied from an opening of a front end of the nozzle 11 onto a substrate W.

On a side face of the nozzle 11, provided is the pair of electrodes 21 and 22, to which DC or AC electric power is fed from an external power source via electric transmission lines (not shown).

The nanosize heater 30 is formed of a material having a higher melting point and a relatively larger volume resistivity. In general, such a heater can be formed of tungsten, graphite or the like, preferably a carbon nanotube as described above, which has a larger allowable current density and a larger strength even at a high temperature.

Each end portion of the nanosize heater 30 is fixed to each of the electrodes 21 and 22 using fusion or pressure bonding. The nanosize heater 30 is curved with a U-shape and located so as to pass over the opening of the nozzle 11, thereby effectively heating the source gas flowing through the nozzle 11. Since a carbon nanotube has a higher bending strength, it is more suitable for the curved nanosize heaters 30.

Next, a method for forming a micro thin film will be described below. First, the above-described nanosize heater-mounted nozzle 10 is positioned closely to the surface of the substrate W. Next, the source gas is locally supplied through the nanosize heater-mounted nozzle 10 toward the substrate W, while the source gas is heated around the opening of the nozzle 11 by energizing the nanosize heater 30.

Then, thermal decomposition reaction and/or chemical reaction of the source gas is locally caused to generate chemical species M, including atoms, molecules, ions and radicals. The chemical species M are deposited on the substrate W to form a pinpoint micro thin film. Deposition area of the thin film can be controlled by adjusting various parameters, such as opening area of the nozzle 11, size and shape of the nanosize heater 30, and/or distance between the nozzle 11 or the nanosize heater 30 and the substrate W.

In addition, such a micro thin film having any number of layers, any material of layer, and/or any thickness of layer can be locally formed with a desired pattern by controlling a variety of the source gas, time of deposition and/or the position of the nozzle.

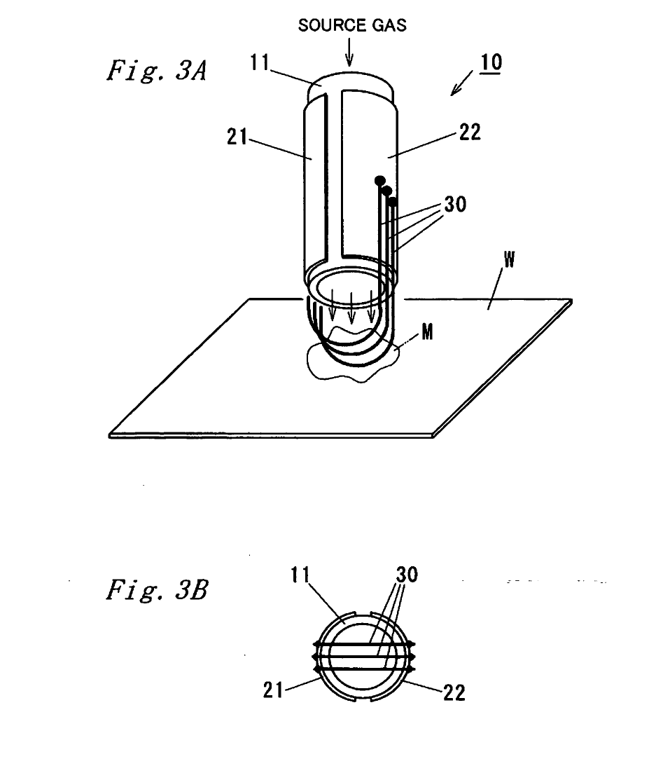

FIG. 3A is a schematic perspective view showing a second embodiment according to the present invention, and FIG. 3B is a bottom plan view thereof. A nanosize heater-mounted nozzle 10 is composed, similarly as shown in FIG. 2A, of a nozzle body 11, a pair of electrodes 21 and 22, and a plurality of nanosize heaters 30 (e.g., three heaters).

The nozzle body 11 is formed of an electrically insulating material, such as quartz or glass, so as to have a tubular shape, e.g., cylinder hollow or rectangle hollow. The inner diameter of the nozzle 11 may be optionally designed depending on spatial resolution during deposition of micro thin films, for example, 100 nm to 2 μm. When a source gas is fed from a gas transfer unit through a gas delivery path (not shown) to a rear end of the nozzle 11, the source gas is locally supplied from an opening of a front end of the nozzle 11 onto a substrate W.

On a side face of the nozzle 11, provided is the pair of electrodes 21 and 22, to which DC or AC electric power is fed from an external power source via electric transmission lines (not shown).

The nanosize heaters 30 are formed of a material having a higher melting point and a relatively larger volume resistivity. In general, such a heater can be formed of tungsten, graphite or the like, preferably a carbon nanotube as described above, which has a larger allowable current density and a larger strength even at a high temperature.

Each end portion of each nanosize heater 30 is fixed to each of the electrodes 21 and 22 using fusion or pressure bonding. The nanosize heaters 30 are curved with a U-shape and located so as to pass over the opening of the nozzle 11, thereby effectively heating the source gas flowing through the nozzle 11. Since a carbon nanotube has a higher bending strength, it is more suitable for the curved nanosize heaters 30.

Next, a method for forming a micro thin film will be described below. First, the above-described nanosize heater-mounted nozzle 10 is positioned closely to the surface of the substrate W. Next, the source gas is locally supplied through the nanosize heater-mounted nozzle 10 toward the substrate W, while the source gas is heated around the opening of the nozzle 11 by energizing the nanosize heaters 30.

Then, thermal decomposition reaction and/or chemical reaction of the source gas is locally caused to generate chemical species M, including atoms, molecules, ions and radicals. The chemical species M are deposited on the substrate W to form a pinpoint micro thin film. Deposition area of the thin film can be controlled by adjusting various parameters, such as opening area of the nozzle 11, size and shape of each nanosize heater 30, and/or distance between the nozzle 11 or the nanosize heaters 30 and the substrate W.

In addition, such a micro thin film having any number of layers, any material of layer, and/or any thickness of layer can be locally formed with a desired pattern by controlling a variety of the source gas, time of deposition and/or the position of the nozzle.

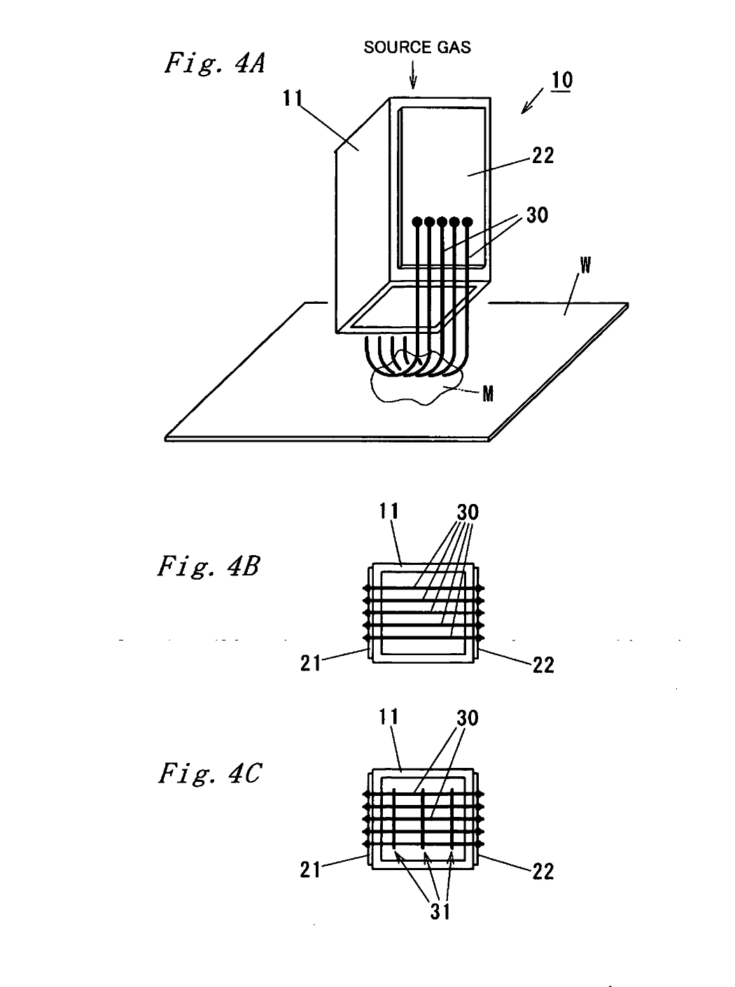

FIG. 4A is a schematic perspective view showing a third embodiment according to the present invention, and FIGS. 4B and 4C are bottom plan views thereof. A nanosize heater-mounted nozzle 10 is composed, similarly as shown in FIG. 2A, of a nozzle body 11, a pair of electrodes 21 and 22, and a plurality of nanosize heaters 30 (e.g., five heaters), in which the nozzle body 11 is formed with a rectangle hollow.

The nozzle body 11 is formed of an electrically insulating material, such as quartz or glass, so as to have a tubular shape. The inner diameter of the nozzle 11 may be optionally designed depending on spatial resolution during deposition of micro thin films, for example, 100 nm to 2 μm. When a source gas is fed from a gas transfer unit through a gas delivery path (not shown) to a rear end of the nozzle 11, the source gas is locally supplied from an opening of a front end of the nozzle 11 onto a substrate W.

On a side face of the nozzle 11, provided is the pair of electrodes 21 and 22, to which DC or AC electric power is fed from an external power source via electric transmission lines (not shown).

The nanosize heaters 30 are formed of a material having a higher melting point and a relatively larger volume resistivity. In general, such a heater can be formed of tungsten, graphite or the like, preferably a carbon nanotube as described above, which has a larger allowable current density and a larger strength even at a high temperature.

Each end portion of each nanosize heater 30 is fixed to each of the electrodes 21 and 22 using fusion or pressure bonding. The nanosize heaters 30 are curved with a U-shape and located so as to pass over the opening of the nozzle 11, thereby effectively heating the source gas flowing through the nozzle 11. Since a carbon nanotube has a higher bending strength, it is more suitable for the curved nanosize heaters 30.

In another example as shown in FIG. 4C, linking members 31 are arranged to intersect the nanosize heaters 30 in a mesh-like manner. The linking members 31 may be formed of a material identical to or different from that of the nanosize heater 30. Coupling of the linking members 31 with the nanosize heaters 30 can reinforce the nanosize heaters 30.

Next, a method for forming a micro thin film will be described below. First, the above-described nanosize heater-mounted nozzle 10 is positioned closely to the surface of the substrate W. Next, the source gas is locally supplied through the nanosize heater-mounted nozzle 10 toward the substrate W, while the source gas is heated around the opening of the nozzle 11 by energizing the nanosize heaters 30.

Then, thermal decomposition reaction and/or chemical reaction of the source gas is locally caused to generate chemical species M, including atoms, molecules, ions and radicals. The chemical species M are deposited on the substrate W to form a pinpoint micro thin film. Deposition area of the thin film can be controlled by adjusting various parameters, such as opening area of the nozzle 11, size and shape of each nanosize heater 30, and/or distance between the nozzle 11 or the nanosize heaters 30 and the substrate W.

In addition, such a micro thin film having any number of layers, any material of layer, and/or any thickness of layer can be locally formed with a desired pattern by controlling a variety of the source gas, time of deposition and/or the position of the nozzle.

The present invention can be utilized in combination with a conventional process which handle an overall substrate, and also can be applied to partial repair or supplement of a thin film.

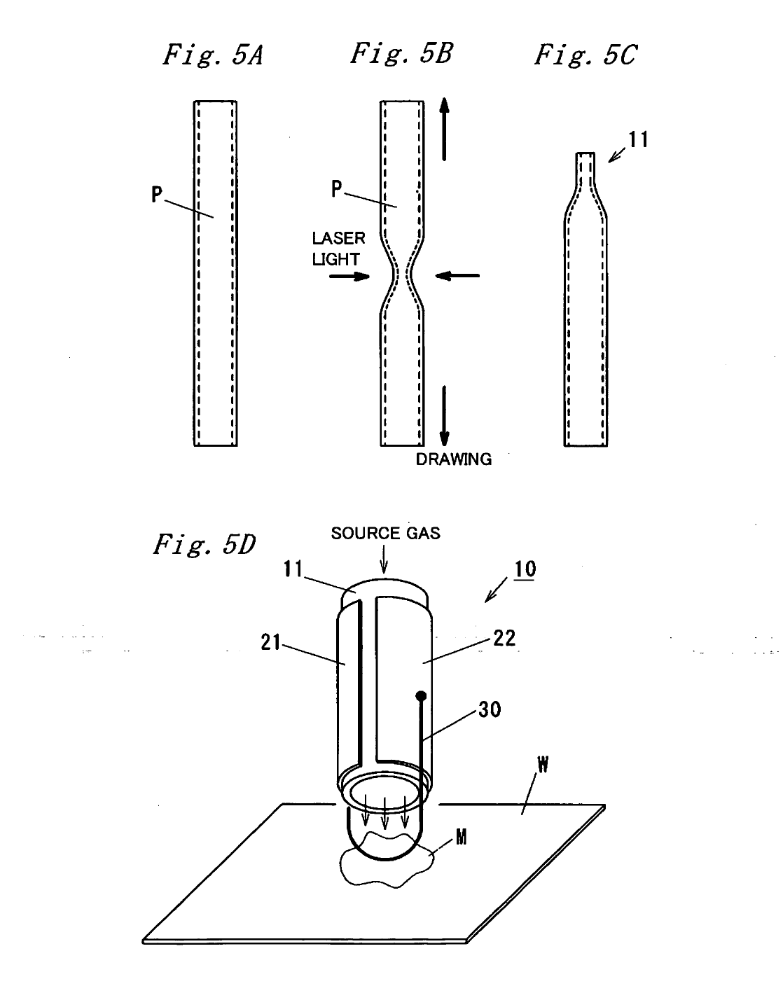

FIGS. 5A to 5D are illustrative views showing a fourth embodiment according to the present invention. Herein, a method for manufacturing a nanosize heater-mounted nozzle will be described below by exemplifying the nanosize heater-mounted nozzle 10 shown in FIG. 2A. Incidentally, the method can be also applied to other nozzles as shown in FIGS. 3A and 4A and any type of nanosize heater-mounted nozzle.

First, as shown in FIG. 5A, a tube P (for example, outer diameter of 1 mm and inner diameter of 0.5 mm) made of quartz or glass, which has a higher heat resistance, is provided. Next, as shown in FIG. 5B, the tube P is partially heated by irradiating the side face of the tube P with laser light from a high-power laser source, such as CO₂ laser. After the tube P is partially melted, it is drawn to slim the outer and inner diameters of the tube P. Then, the cooled and slimmed portion is cut off to obtain a tapered nozzle 11 (for example, outer diameter of 500 nm and inner diameter of 300 nm), as shown in FIG. 5C.

The ultimate outer and inner diameters of the nozzle 11 can be adjusted in a range of several micrometers to several hundred nanometers by controlling the outer and inner diameters of the tube P in use, heating condition and/or drawing condition. In particular, the nozzle 11 is preferably formed of quartz or glass, resulting in the nozzle with excellent heat resistance, strength and chemical stability. It is also easy to obtain the nozzle having desired opening diameter and shape due to excellent workability thereof.

Next, as shown in FIG. 5D, a pair of electrodes 21 and 22 (for example, each thickness of 30 nm to 50 nm) is formed on the side face of the nozzle 11 using vacuum evaporation or sputtering. Between the electrodes 21 and 22, a gap is interposed along the longitudinal direction of the nozzle 11 for preventing short-circuiting.

The electrodes 21 and 22 are preferably formed of a material having a melting point of 1,700 degree-C. or higher, such as platinum Pt (melting point: 1,770 degree-C.), tantalum Ta (m.p.: 2,990 degree-C.), molybdenum Mo (m.p.: 2,620 degree-C.), thereby attaining the nozzle with excellent heat resistance, strength and chemical stability.

In a case of insufficient insulating resistance between the electrodes 21 and 22, there is a possibility that a minute conductive portion may reside in the gap between the electrodes. For this countermeasure, after the electrodes are formed on the side face of the nozzle, the conductive portion between the electrodes is evaporated by supplying an excessive electric current between the electrodes in vacuum, thereby remarkably suppressing a leakage current, and attaining a higher insulating resistance between the electrodes, for example, several kilo-ohms to several tens mega-ohms. Since this treatment may considerably raise up the heating temperature, the nozzle 11 is preferably formed of quartz or heat-resistant glass. Alternatively to such electric current treatment, the conductive portion between the electrodes can be removed using FIB (focused ion beam).

Next, a nanosize heater 30 of a carbon nanotube is connected to the electrodes 21 and 22 so as to pass over the opening of the nozzle 11. This work requires high accuracy, which can be attained by means of manipulation by directly viewing it with a SEM (scanning electron microscope). After one end of the nanosize heater 30 is fixed to the electrode 22, and then it is generally curved to a loop shape by supporting it with another needle or the like, and then another end of the nanosize heater 30 is fixed to the electrode 21. For one approach to fix the carbon nanotube, a thin film by electron beam induced deposition can be used.

Next, each of the portions connected between the electrodes 21 and 22 and the nanosize heater 30 is spot-irradiated with an electron beam of the SEM, while the nanosize heater 30 is energized with a current (for example, several microamperes to several tens microamperes). Thus, heat is generated at a portion having a higher contact resistance, thereby evaporating impurities residing in the portion between nanosize heater 30 and the electrodes 21 and 22, consequently the contact resistance of the connected portion is reduced. At this time the connected portion is subject to a relatively high temperature, hence the electrodes 21 and 22 is preferably formed of a material having a higher melting point, such as Pt, Ta, Mo.

After completing the above-described steps, such a nanosize heater-mounted nozzle as shown in FIG. 5D can be obtained.

Next, evaluation of the nanosize heater-mounted nozzle will be described below. When a electric current flows through a nanosize heater formed of a carbon nanotube to emit radiation, temperature of the nanosize heater can be measured by analyzing the emission spectrum using Planck's black body radiation law. A current of several microamperes to several hundreds microamperes can pass through the carbon nanotube, even though depending on individual difference of carbon nanotubes. In this case it can reach a temperature as much as 3,000 K in vacuum (about 10⁻⁵ Pa). Incidentally, a sublimation point of graphite is 2,000 K at the same degree of vacuum, hence the current passing through the nanosize heater is preferably set with an upper limit of this temperature. Further, an upper limit of current for the nanosize heater does not always depend on diameter and length of the nanotube, but depends on individual difference of nanotubes.

In a case a carbon nanotube, through which a current can flow effectively, is connected to Pt electrodes with a thickness of 30 nm, when a current as much as 300 μA flows therethrough, the Pt electrodes begin evaporating before the nanotube generates heat. At this time the temperature of the nanotube reaches about 1,000 K. Hence the nozzle is preferably formed of heat-resistant glass, such as quartz.

Next, an example of process using a nanosize heater will be described below. Experiment was conducted in a vacuum of about 10⁻⁵ Pa. A nanosize heater was approached several tens nanometers close to an amorphous carbon film (about 30 nm), which has been deposited using electron beam induced deposition, and then the carbon film was locally heated by energizing the heater for 1 to 2 minutes, with the heater current of about 100 μA and the temperature of 2,500 to 3,000 K. Consequently, the amorphous carbon film was evaporated within a region of several hundreds nanometers around the nanosize heater.

Next, an example of process using a nanosize heater-mounted nozzle will be described below. First, the nozzle 11 shown in FIG. 5C was filled with ethyl alcohol, and then the opposite opening was sealed with epoxy adhesives. Next, the nozzle 11 filled with ethyl alcohol was attached to a manipulator of SEM, and then held 1 μm or shorter close to a work substrate. Next, the nanosize heater 30 was energized in a vacuum of about 10⁻⁵ Pa. Thus, molecules of ethyl alcohol jumping out of the nozzle 11 was decomposed by heating of the nanosize heater 30, causing a deposition with a diameter of several micrometers, which was presumed as carbon, on the work substrate.

### INDUSTRIAL APPLICABILITY

According to the present invention, localized supply and localized heating of a source gas can be realized, thereby forming a thin film in an extremely small region on a substrate. Consequently, damage to the whole substrate caused by processes is remarkably reduced as compared to the conventional method, and the source gas and energy required for processes can be economized.

1. A nanosize heater-mounted nozzle comprising:
a nozzle for locally supplying a source gas toward a substrate; and
a nanosize heater for heating the source gas, located in the vicinity of an opening of the nozzle.

2. The nanosize heater-mounted nozzle according to claim 1, wherein the nanosize heater is composed of carbon nanotube.

3. The nanosize heater-mounted nozzle according to claim 1, wherein the nozzle is formed of an electrically insulating material, and a pair of electrodes is located on a side face of the nozzle, and the nanosize heater is connected between the electrodes so as to pass over the opening of the nozzle.

4. The nanosize heater-mounted nozzle according to claim 3, wherein the nozzle is formed of quartz or heat-resistant glass.

5. The nanosize heater-mounted nozzle according to claim 3, wherein the electrodes are formed of a material having a melting point of 1,700 degree-C. or higher.

6. A method for forming a micro thin film including steps of:
positioning the nanosize heater-mounted nozzle, according to claim 1, closely to a surface of a substrate;
locally supplying a source gas toward the substrate through the nanosize heater-mounted nozzle; and
heating the source gas around an opening of the nozzle while energizing the nanosize heater.

7. A method for manufacturing a nanosize heater-mounted nozzle including steps of:
partially heating a tube formed of an electrically insulating material to shape a tapered nozzle by drawing;
forming a pair of electrodes on a side face of the nozzle; and
connecting a nanosize heater between the electrodes so as to pass over an opening of the nozzle.

8. The method for manufacturing a nanosize heater-mounted nozzle, according to claim 7, further including a step of evaporating a conductive portion between the electrodes by supplying a current between the electrodes, after forming the pair of electrodes on the side face of the nozzle.

9. The method for manufacturing a nanosize heater-mounted nozzle, according to claim 7, further including a step of irradiating with an electron beam the portion connected between each of the electrodes and the nanosize heater, after connecting the nanosize heater between the electrodes.
